(19) United States
(12) Patent Application Publication
(10) Pub. No.: US 2015/0255629 A1
(43) Pub. Date: Sep. 10, 2015

(54) SEMICONDUCTOR DEVICE

(71) Applicant: KABUSHIKI KAISHA TOSHIBA, Tokyo (JP)

(72) Inventors: Ryohei GEJO, Kanazasa Ishikawa (JP); Bungo TANAKA, Ageo Saitama (JP)

(21) Appl. No.: 14/474,299

(22) Filed: Sep. 2, 2014

(30) Foreign Application Priority Data
Mar. 5, 2014 (JP) 2014-043040

(51) Int. Cl. H01L 29/868; H01L 29/739; H01L 27/06; H01L 29/66

(52) U.S. Cl. CPC H01L 29/868; H01L 29/6609; H01L 29/7395; H01L 27/0664

(57) ABSTRACT

A semiconductor device includes: a first semiconductor layer of a first conductive type having a first side and an opposed second side; a second semiconductor layer of a second conductive type formed on the first side; a third semiconductor layer of a second conductive type partially formed in the second semiconductor layer; a fourth semiconductor layer of a first conductive type formed between the first semiconductor layer and the second semiconductor layer, the fourth semiconductor layer facing the third semiconductor layer, the fourth semiconductor layer including a first region which has a first dopant concentration and a second region which has a second dopant concentration higher than the first dopant concentration; a fifth semiconductor layer of a first conductive type formed on the second side; and a conductor contacting the first semiconductor layer, the second semiconductor layer and the third semiconductor layer via an insulation film.

### CROSS-REFERENCE TO RELATED APPLICATION

This application is based upon and claims the benefit of priority from Japanese Patent Application No. 2014-043040, filed Mar. 5, 2014, the entire contents of which are incorporated herein by reference.

### FIELD

Embodiments described herein relate generally to a semiconductor device.

### BACKGROUND

An IGBT (Insulated Gate Bipolar Transistor) has gained wide acceptance as a power semiconductor device which has high breakdown strength and can switch a large electric current. When the IGBT is used as a switching element, pin diodes are commonly configured in parallel as part of a combined switching circuit.

Recently, an integrated semiconductor device having both an IGBT and pin diodes has been extensively studied but not yet effectively produced. A pin diode, which may be integrated into a semiconductor device and has better reverse recovery capability when the pin diode is turned off, is also desired.

### DESCRIPTION OF THE DRAWINGS

FIG. 1A and FIG. 1B are views showing a semiconductor device according to a first embodiment, in which FIG. 1A is a plan view of the semiconductor device having the overlying second anode electrode removed for clarity of viewing the underlying structure, and FIG. 1B is a cross-sectional view taken along a line A-A in FIG. 1A and viewed in the direction indicated by arrows and including the second anode electrode therein.

FIG. 2A and FIG. 2B are cross-sectional views showing the manner of operation of the semiconductor device according to the first embodiment and the manner of operation of a semiconductor device of a comparison example in a comparative manner.

FIG. 3A to FIG. 3C are cross-sectional views sequentially showing steps of manufacturing the semiconductor device according to the first embodiment.

FIG. 4A and FIG. 4B are cross-sectional views sequentially showing steps of manufacturing the semiconductor device according to the first embodiment.

FIG. 5A and FIG. 5B are cross-sectional views sequentially showing steps of manufacturing the semiconductor device according to the first embodiment.

FIG. 6A and FIG. 6B are views showing a semiconductor device according to a second embodiment, in which FIG. 6A is a plan view of the semiconductor device having the second anode electrode thereof removed for clarity of showing the underlying structure, and FIG. 6B is a cross-sectional view taken along a line A-A in FIG. 6A and viewed in the direction indicated by arrows, having the second anode electrode therein.

FIG. 7A and FIG. 7B are views showing a semiconductor device according to a third embodiment, in which FIG. 7A is a plan view of the semiconductor device having the second anode electrode thereof removed for clarity of showing the underlying structure, and FIG. 7B is a cross-sectional view taken along a line A-A in FIG. 7A and viewed in the direction indicated by arrows, having the second anode electrode therein.

FIG. 8A and FIG. 8B are views showing a semiconductor device according to a fourth embodiment, in which FIG. 8A is a plan view of the semiconductor device having the second anode electrode thereof removed for clarity of showing the underlying structure, and FIG. 8B is a cross-sectional view taken along a line A-A in FIG. 8A and viewed in the direction indicated by arrows, having the second anode electrode therein.

FIG. 9A and FIG. 9B are views showing a semiconductor device according to a fifth embodiment, in which FIG. 9A is a plan view of the semiconductor device having the second anode electrode thereof removed for clarity of showing the underlying structure, and FIG. 9B is a cross-sectional view taken along a line A-A in FIG. 9A and viewed in the direction indicated by arrows, having the second anode electrode therein.

### DETAILED DESCRIPTION

According to an embodiment, there is provided a semiconductor device which has enhanced reverse recovery capability.

In general, according to one embodiment, a semiconductor device includes: a first semiconductor layer of a first conductive type having a first side and a second side thereof positioned opposite to the first side; a second semiconductor layer of a second conductive type formed on the first side; a third semiconductor layer of a second conductive type partially formed in the second semiconductor layer; a fourth semiconductor layer of a first conductive type formed between the first semiconductor layer and the second semiconductor layer, the fourth semiconductor layer facing the third semiconductor layer, the fourth semiconductor layer including a first region which has a first dopant concentration and a second region which has a second dopant concentration higher than the first dopant concentration; a fifth semiconductor layer of a first conductive type formed on the second side; a conductor brought into contact with the first semiconductor layer, the second semiconductor layer and the third semiconductor layer via an insulation film; a first electrode which is electrically connected with the second semiconductor layer, the third semiconductor layer and the conductor; and a second electrode which is electrically connected with the fifth semiconductor layer.

Hereinafter, embodiments are explained by reference to drawings.

### First Embodiment

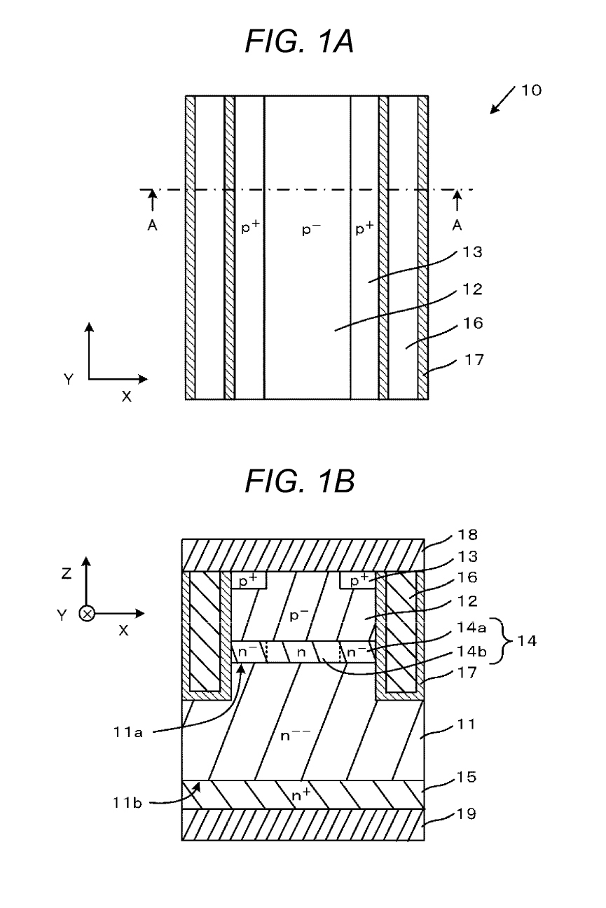

A semiconductor device according to this embodiment is explained by reference to FIG. 1 A and FIG. 1B. FIG. 1A and FIG. 1B are views showing the semiconductor device according to this embodiment, wherein FIG. 1A is a plan view of the semiconductor device, wherein the second anode electrode (18) is removed to show the underlying structure, and FIG. 1B is a cross-sectional view (including the second anode layer 18 therein) taken along a line A-A in FIG. 1A and viewed in the direction indicated by arrows. In the plan view, an uppermost layer (first electrode described later) is omitted.

The semiconductor device according to this embodiment comprises an integrated pin diode and power semiconductor device (not shown), for example, an IGBT (Insulated Gate Bipolar Transistor) thus functioning as a reflux diode (free wheel diode).

As shown in FIG. 1A and FIG. 1B, a semiconductor device according to this embodiment (hereinafter referred to as “pin diode”) 10 includes: a first semiconductor layer 11 of a first conductive type; a second semiconductor layer 12 of a second conductive type; third semiconductor layers 13 of a second conductive type; a fourth semiconductor layer 14 of a first conductive type; and a fifth semiconductor layer 15 of a first conductive type. The pin diode 10 may be integrally formed with power semiconductor devices, such as an IGBT or other semiconductor device, formed on the same semiconductor substrate and using some or all of the same film layers as those used in the pin diode 10, to form a semiconductor device chip having the pin diode 10 and another semiconductor device integrated together.

In the explanation made hereinafter, as one example, it is assumed that a first conductive type is an n type, and a second conductive type is a p type. The description of n⁺, n, n⁻, n⁻⁻, and p⁻, p and p⁻ in FIG. 1A and FIG. 1B indicate relative levels of dopant concentration among respective n and p dopant types. That is, n⁺ indicates that an n-type dopant concentration is relatively higher than an n-type dopant concentration of n, n⁻ indicates that an n-type dopant concentration is relatively lower than an n-type dopant concentration of n, n⁻⁻ indicates that an n-type dopant concentration is relatively lower than an n-type dopant concentration of n⁻. p⁺ indicates that a p-type dopant concentration is relatively higher than a p-type dopant concentration of p, and p⁻ indicates that a p-type dopant concentration is relatively lower than a p-type dopant concentration of p.

The direction extending through the first to fifth semiconductor layers 11, 12, 13, 14, 15 is assumed as the Z direction of the coordinate system shown in FIG. 1, one direction which is orthogonal to the Z direction is assumed as the X direction, and the direction which is orthogonal to both the Z direction and the X direction is assumed as the Y direction, as shown in the coordinate system of FIG. 1.

The n-type first semiconductor layer (hereinafter referred to as “n base layer”) 11 includes a first surface 11a and a second surface 11b on a side opposite to a side on which the first surface 11a is formed. The p-type second semiconductor layer (hereinafter referred to as “p anode layer”) 12 is formed over the first surface 11a of the n base layer 11.

The p-type third semiconductor layers (hereinafter referred to as “p emitter layers”) 13 are partially formed on and in the p anode layer 12. One end surface of each p emitter layer 13 is brought into contact with an upper surface of the p anode layer 12. Each p emitter layer 13 extends in the Y direction into the p anode layer 12, and is brought into contact with a conductor 16 at the edges thereof in the x direction via an insulation film 17 described later herein.

The n-type fourth semiconductor layer (hereinafter referred to as “n barrier layer”) 14 is formed between the n base layer 11 and the p anode layer 12. A first region 14a of the n barrier layer 14 is positioned below, and spaced from the p emitter layers 13 by the p anode layer. A second region 14b of the n barrier layer 14 is disposed between opposed first regions. The n type dopant concentration in each first region 14a is lower than the n type dopant concentration in the second region 14b. That is, the n barrier layer 14 has a dopant concentration distribution in the X direction, which is greater at the center, along the x direction, of the pin diode 10.

The n-type fifth semiconductor layer (hereinafter referred to as “n cathode layer”) 15 is formed on the second surface 11b of the n base layer 11.

Each conductor (first anode electrode) 16 is formed such that the conductor 16 extends along a side of the p anode layer 12 and below the surface of the first surface 11a, i.e., into the n base layer. The first anode electrode 16 is also formed such that the first anode electrode 16 extends in the Y direction (first direction), as best shown in FIG. 1A. A plurality of first anode electrodes 16 are formed such that the p emitter layers 13 and the p anode layer are located therebetween, and a side of each p emitter layer is disposed adjacent to a first anode electrode 16.

An insulation film 17 is formed between the first anode electrode 16 and adjacent portions of the n base layer 11, the p anode layer 12, the p emitter layer 13, and the first anode electrode 16 and the n barrier layer 14.

A first electrode (hereinafter referred to as “second anode electrode”) 18 is formed such that the second anode electrode 18 is in ohmic contact with the p anode layer 12, the p emitter layers 13, and the first anode electrodes 16 on one side thereof.

A second electrode (hereinafter referred to as “cathode electrode”) 19 is formed such that the cathode electrode 19 is in ohmic contact with the n cathode layer 15 on the side thereof opposite to base layer 11.

The n base layer 11, the p anode layer 12, the p emitter layers 13, the n barrier layer 14, and the n cathode layer 15 are formed, for example, of a silicon semiconductor material layer doped with a dopant, for example. The first anode electrode 16 is, for example, formed of a polysilicon film doped with a dopant.

The insulation film 17 is formed as a silicon oxide thin film layer, for example. The second anode electrode 18 and the cathode electrode 19 are made of a metal, such as gold, or aluminum, which can form an ohmic contact with silicon, for example.

The dopant concentration in the n base layer 11 is between approximately 1×10¹³ dopant atoms cm⁻³ and 1×10¹⁵ dopant atoms cm⁻³. The thickness of the n base layer 11 is between approximately 50 μm and 500 μm, for example.

The dopant concentration in the p anode layer 12 is between approximately 1×10¹⁷ dopant atoms cm⁻³and 1×10¹⁸ dopant atoms cm⁻³, for example. The thickness of the p anode layer 12 is greater than or equal to approximately 0.5 μm and less than or equal to approximately 5 μm, for example.

The p dopant concentration in the p emitter layer 13 is higher than the p dopant concentration in the p anode layer 12. The dopant concentration in the p emitter layer 13 is approximately 1×10²⁰ dopant atoms cm⁻³, for example. The thickness of the p emitter layer 13 is approximately 2 μm or less, for example.

The n dopant concentration in the n barrier layer 14 is higher than the n dopant concentration in the n base layer 11. A first dopant concentration in the first region 14a of the n barrier layer 14 is approximately 0.5×10¹⁷ dopant atoms cm⁻³ or less, for example. The n dopant concentration in the second region 14b of the n barrier layer 14 is approximately 1×10¹⁷ dopant atoms cm⁻³ or less, for example. The thickness of the n barrier layer 14 is between approximately 0.5 μm and 6 μm, for example.

The n dopant concentration in the n cathode layer 15 is higher than the n dopant concentration in the first semiconductor layer 11. The n dopant concentration in the fifth semiconductor layer 15 is between approximately 1×10¹⁸ dopant atoms cm⁻³ 1×10²¹ dopantatoms cm⁻³ or less, for example. The thickness of the n cathode layer 15 is approximately 2 μm or less, for example.

The spacing distance between the first anode electrodes 16 (distance between the centers of the first anode electrodes 16) in the X direction is greater than or equal to approximately 3 μm and less than or equal to approximately 18 μm, for example. The width of the first anode electrode 16 is greater than or equal to approximately 0.5 μm and less than or equal to approximately 2 μm, for example. The thickness of the insulation film 17 is greater than or equal to approximately 0.1 μm and less than or equal to approximately 0.5 μm, for example.

A plurality of pin diodes 10 according to this embodiment maybe arranged in the X direction in a state where the plurality of pin diodes 10 are electrically connected in common by the first anode electrode 16.

Next, a function and the manner of operation of the pin diode 10 according to this embodiment are explained.

The dopant concentration in the n base layer 11 is sufficiently low, in comparison to other doped layers, to be considered as an intrinsic semiconductor layer (i layer). Accordingly, the p anode layer 12, the n base layer 11 and the n cathode layer 15 together function as a pin diode. The n base layer 11 has a sufficiently large thickness for the pin diode 10 to have a high breakdown strength. Each p emitter layer 13 functions as a contact layer between the p anode layer 12 and the second anode electrode 18.

The first anode electrodes 16 are provided to ensure a sufficiently high breakdown strength by expanding a depletion layer formed on a pn junction interface in the lateral direction when a reverse bias is applied to the pin diode 10. Further, the first anode electrodes 16 are provided as trench isolation for electrically separating the pin diode 10 from a semiconductor device different from the pin diode 10, for example, an adjacent IGBT.

The n barrier layer 14 has the graded n doped structure for controlling the injection efficiency of carriers injected into the n base layer 11 when the pin diode 10 is forwardly biased. The n barrier layer 14 is also provided for controlling a discharge path through which excess carriers stored in the n base layer 11 are discharged to the p emitter layers 13 when the pin diode 10 is turned off.

The first, n-doped, regions 14a of the n barrier layer 14 mainly contribute to the control of the discharge path, and the second, n doped, region 14b of the n barrier layer 14 mainly contributes to the control of the injection efficiency of carriers.

When the pin diode 10 is forward biased by applying a positive voltage to the second anode electrode 18 and by applying a negative voltage to the cathode electrode 19, holes are injected into the n base layer 11 from the p anode layer 12 and electrons are injected into the n base layer 11 from the n cathode layer 15 so as to satisfy an electroneutrality condition.

Hereinafter, excess electrons and holes stored in the n base layer 11 are referred to as excess carriers. As a result of such electron injection, conductivity modulation is generated in the n base layer 11 by excess carriers and hence, the resistance in the n base layer 11 becomes extremely small. Accordingly, the n base layer 11 is brought into a conductive state.

Holes are firstly injected into the n barrier layer 14 from the anode layer 12, and so the hole concentration is lowered in the n barrier layer 14. This is because the n dopant concentration in the n barrier layer 14 is higher, and significantly higher, than the n dopant concentration in the n base layer 11 so that the hole diffusion length becomes small. That is, the injection efficiency of holes from the p anode layer 12 changes depending on the dopant concentration of the n barrier layer 14.

On the other hand, when the pin diode 10 is turned off, that is, in a process where a state of the pin diode 10 transcends to a reverse direction biased state from a forward direction biased state, excess carriers in the n base layer 11 are preferentially discharged from a region where a diffusion length is large, that is, from a region where a dopant concentration is low.

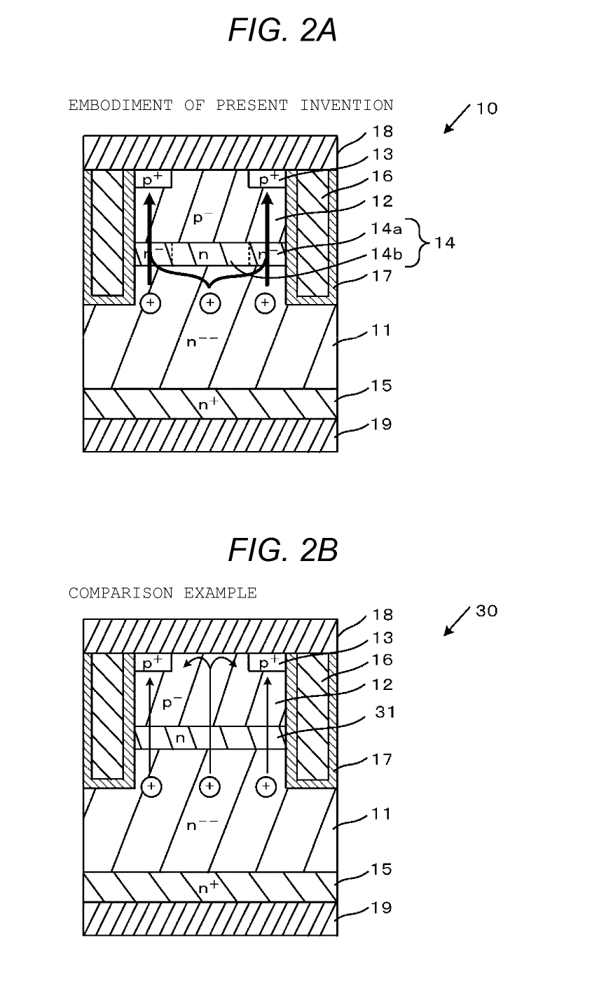

FIG. 2A and FIG. 2B are views comparing the manner of operation of the pin diode 10 and the manner of operation of a pin diode of a comparison example, wherein FIG. 2A is a cross-sectional view showing the manner of operation of the pin diode 10, and FIG. 2B is a cross-sectional view showing the manner of operation of a pin diode 30 of the comparison example.

The pin diode 30 of the comparison example is a pin diode having an n barrier layer 31 where a dopant concentration in the X direction is uniform. Firstly, the manner of operation of the pin diode 30 of the comparison example is explained.

As shown in FIG. 2B, in the pin diode 30 of the comparison example, the dopant concentration in the n barrier layer 31 is uniform and hence, when the pin diode 30 is turned off, the path for discharging excess carriers in the n base layer 11 extends over the entire span of the n barrier layer 31 between adjacent first anode electrodes 16.

The p dopant concentration in the p anode layer 12 is lower than the p dopant concentration in the p emitter layer 13 and hence, the contact resistance between the p anode layer 12 and the second anode electrode 18 is high. Further, there may be a case where the p anode layer 12 and the second anode electrode 18 exhibit a Schottky junction characteristic.

As a result, a current concentration occurs in a region of an upper portion of the p anode layer 12 between the p emitter layers 13 and hence, diode reverse recovery capability is lowered.

On the other hand, as shown in FIG. 2A, in the pin diode 10 according to this embodiment, the n dopant concentration in the first regions 14a of the n barrier layer 14 below the p emitter layers 13 is lower than the n dopant concentration in the second region 14b of the n barrier layer 14 and hence, when the pin diode 10 is turned off, excess carriers in the n base layer 11 are discharged preferentially through the first regions 14a. That is, the discharge path for excess carriers is limited to the first regions 14a.

As a result, excess carriers may be rapidly extracted to the p emitter layers 13 through the first regions 14a and hence, reverse recovery capability may be enhanced. The first dopant concentration in the first regions 14a may be suitably set corresponding to a target, i.e., desired, reverse recovery capability.

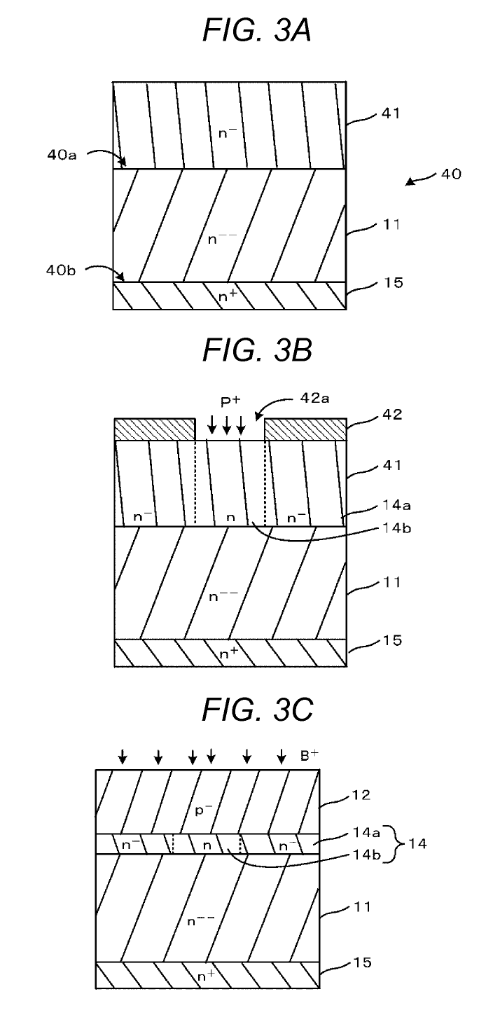

Next, a method of manufacturing the pin diode 10 is explained. FIG. 3A to FIG. 5B are cross-sectional views sequentially showing the method of manufacturing the pin diode 10.

As shown in FIG. 3A, an n-type silicon substrate 40 is provided. Phosphorus ions (P⁺) are injected into the substrate 40 a first surface 40a of the silicon substrate 40 by an ion implantation method, for example, thus forming an n silicon layer 41 having a dopant concentration equal to the first dopant concentration in the first regions 41a of the n barrier layer 14. The thickness of the n silicon layer 41 is the sum of the thicknesses of the n barrier layer 14 and the p doped anode layer 12.

Phosphorus ions (P⁺) are also injected into the substrate, for example into the back surface thereof to the second surface 40b of the silicon substrate 40 by an ion implantation method, for example, thus forming the n doped cathode layer 15. The non-implanted portions of the silicon substrate 40 remaining between the n silicon layer 41 and the n cathode layer 15 becomes the base layer 11. The n cathode layer 15 may also be formed by thermally diffusing an n type dopant thereinto.

As shown in FIG. 3B, a resist film 42 having an opening 42a corresponding to a region of the n barrier layer 14 where the second region 14b is to be formed is formed on the n silicon layer 41 by photolithography methods, for example.

P⁺ dopant ions are injected into the n silicon layer 41 by an ion implantation method through the opening 42a of the resist film 42 using the resist film 42 as a mask, for example, thus forming the second region 14b of the n type barrier layer 14. Regions of the n barrier layer 14 to which P⁺ is not injected form the first regions 14a.

As shown in FIG. 3C, the resist layer 42 has been removed, and B⁺ ions are injected into an upper portion of the n doped silicon layer 41 by an ion implantation method, for example. Due to such injection of B⁺ ions, the upper portion of the n doped silicon layer 41 becomes p doped and forms the p doped anode layer 12. The ion energy of the B⁺ ions is selected such that the ions do not penetrate the entire depth of the n doped silicon layer 41, and thus the previously n doped regions thereof form the n doped barrier layer 14 having the opposed first regions 14a and the intermediate second region 14b.

The p anode layer 12 may also be formed on the n doped barrier layer 14 by a vapor-phase growth method which uses silane (SiH₄) as a process gas, and diborane (B₂H₆) as a dopant gas, for example.

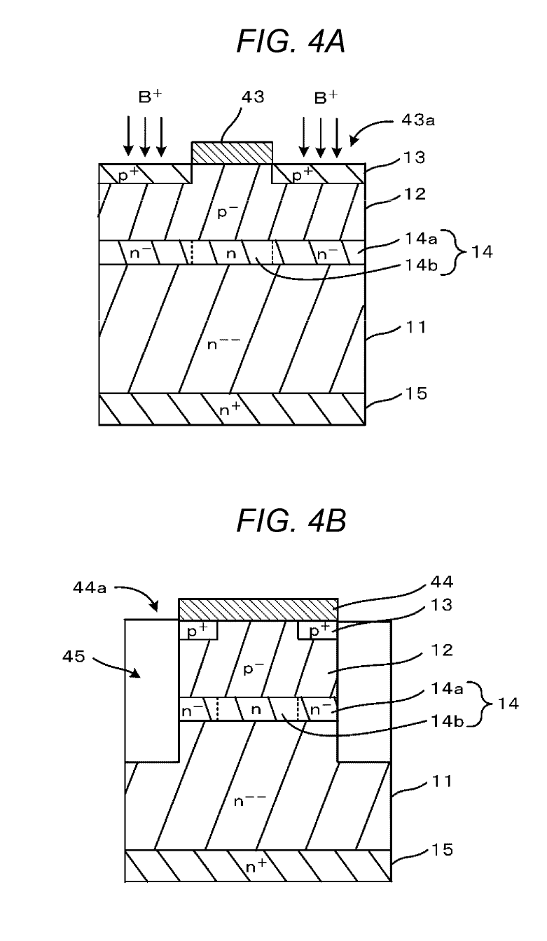

As shown in FIG. 4A, a resist film 43, having openings 43a corresponding to regions where the p emitter layers 13 are to be formed, is formed on the p anode layer 12 by a photolithographic method, for example. The first regions 14a of the n barrier layer 14 are positioned below the openings 43a in the resist film 43.

Boron ions (B⁺) are injected into the p anode layer 12 by an ion implantation method using the resist film 43 as a mask, for example. The p doped emitter layers 13 are thus formed in the p doped anode layer 12 by implanting of boron ions, wherein one end surface of each p emitter layer 13 is co-extensive with the upper surface of the p anode layer 12. The resist film 43 is then removed.

As shown in FIG. 4B, a resist film 44 having openings 44a corresponding to regions where the first anode electrodes 16 are to be formed is formed on the p doped anode layer 12 using a photolithographic method, for example.

Using the resist film 44 as a mask, the p doped emitter layers 13, the p doped anode layer 12, the n doped barrier layer 14 and the n doped base layer 11 are etched until an etched trench is formed which extends to a middle portion of the n doped base layer 11, using an RIE (Reactive Ion Etching) method using a fluorine gas, for example. Due to such etching, trenches 45 which extend into the n doped base layer 11 from the upper surface of the p doped anode layer 12 are formed. The resist film 44 is then removed.

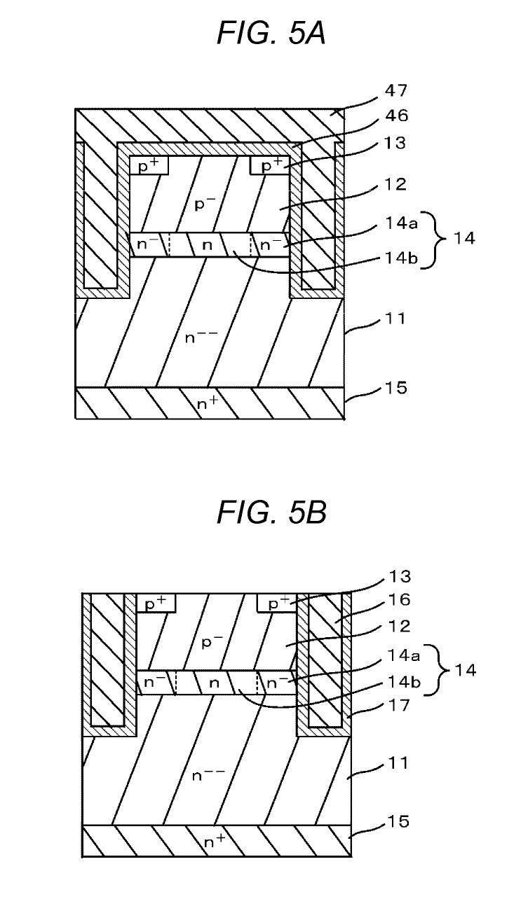

As shown in FIG. 5A, a silicon oxide film 46 is grown on inner surfaces of the trenches 45, the upper surface of the p doped anode layer 12 and upper surfaces of the p doped emitter layers 13 by a thermal oxidation method, for example. To allow a doped polysilicon film 47 to fill inner portions of the trenches 45, the polysilicon film 47 is formed by a CVD method using silane (SiH₄) as a process gas and diborane (B₂H₆) as a dopant gas, for example.

As shown in FIG. 5B, the polysilicon film 47 extending above the surface of the p doped emitter 13 and p doped anode 12 layers is removed by a CMP (Chemical Mechanical Polishing) method, for example, until the silicon oxide film 46 is exposed. The exposed silicon oxide film 46 is then etched by wet etching using an aqueous solution containing hydrofluoric acid, for example, until the p doped anode layer 12 and the p doped emitter layers 13 are exposed. The remaining silicon oxide film 46 forms the insulation film 17. The remaining polysilicon film 47 forms the first anode electrodes 16.

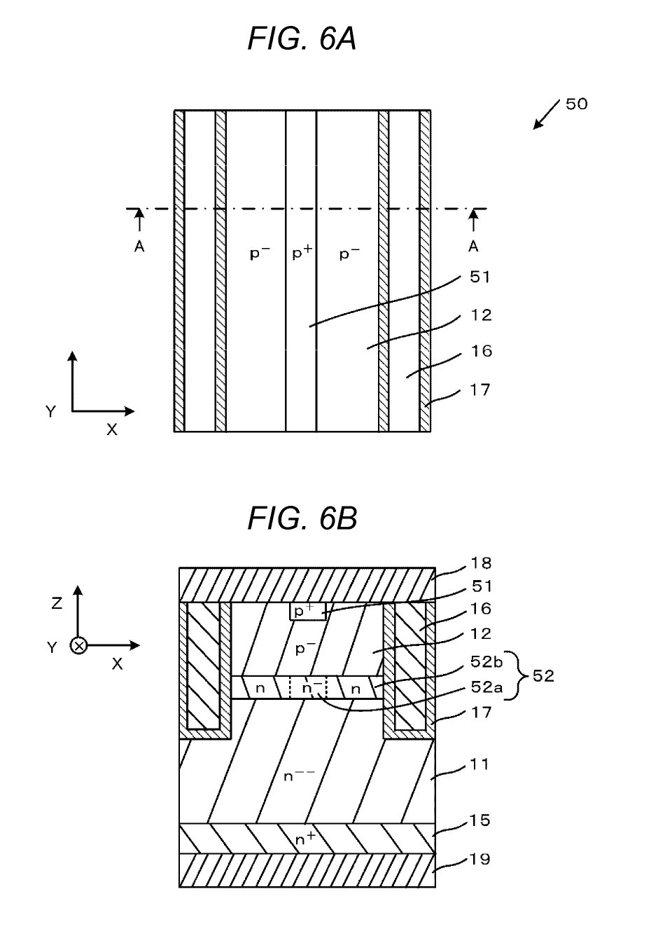

Lastly, an aluminum film is formed on the p anode layer 12, the p emitter layers 13 and the first anode electrodes 16 by a sputtering method, for example, thus forming the second anode electrode 18. In the same manner, the cathode electrode 19 is formed on the n cathode layer 15, resulting in the diode structure shown in FIG. 6B.

As a result of such process steps, the pin diode 10 shown in FIG. 1A and FIG. 1B is obtained.

As has been explained heretofore, in the pin diode 10 according to this embodiment, in the n doped barrier layer 14, the n dopant concentration in the first regions 14a which are positioned below the p doped emitter layers 13 is lower than the n dopant concentration in the second region 41b thereof.

Accordingly, when the pin diode 10 is turned off, a path for discharging excess carriers in the n doped base layer 11 is limited to the first regions 14a. As a result, excess carriers may be rapidly extracted to the p doped emitter layers 13 through the first regions 14a and hence, it is possible to form a pin diode 10 having high reverse recovery capability.

Although the explanation has been made with respect to the case where the first conductive type is an n type and the second conductive type is a p type in this embodiment, the substantially same advantageous effects may be acquired even when the first conductive type is a p type and the second conductive type is an n type.

The explanation has been made with respect to the case where the n doped base layer 11, the p doped anode layer 12, the p doped emitter layers 13, the n doped barrier layer 14 and the n doped cathode layer 15 are all formed of a silicon semiconductor layer. However, the substantially same advantageous effects maybe obtained even when the n doped base layer 11, the p doped anode layer 12, the p doped emitter layers 13, the n doped barrier layer 14 and the n doped cathode layer 15 are formed of a semiconductor layer different from a silicon semiconductor layer, for example, a compound semiconductor layer made of SiC, GaN or the like.

### Second Embodiment

A semiconductor device according to this embodiment is explained by reference to FIG. 6A and FIG. 6B. FIG. 6A and FIG. 6B are views showing the semiconductor device according to this embodiment, wherein FIG. 6A is a plan view of the semiconductor device with the second anode electrode 18 removed for clarity, and FIG. 6B is a cross-sectional view taken along a line A-A in FIG. 6A and viewed in the direction indicated by arrows and including the second anode electrode 18.

In this embodiment, the constitutional elements identical with the corresponding constitutional elements according to the first embodiment are given the same reference numbers, and hence the explanation of the identical constitutional elements is omitted, and only the elements which differ from the corresponding elements according to the first embodiment are explained. The point which makes this embodiment different from the first embodiment lies in that the p doped emitter layer extends in the Y direction, and is spaced from both adjacent first anode electrodes 16.

That is, as shown in FIG. 6A and FIG. 6B, in a pin diode 50 according to this embodiment, a p doped emitter layer 51 extends in the Y direction intermediate of the first anode electrodes 16 which likewise extend in the Y direction. The p doped emitter layer 51 is formed at a central portion of the p doped anode layer 12 such that the p doped emitter layer 51 is generally centered between adjacent first anode electrodes.

A first region 52a of an n doped barrier layer 52 is arranged below the p doped emitter layer 51. Second regions 52b of the n doped barrier layer 52 are arranged on both sides of the first region 52a. The second regions 52b of the n doped barrier layer 52 have a higher n dopant concentration than the n dopant concentrations of the first region 52a

In this embodiment, it is sufficient that the p doped emitter layer 51 extends in the Y direction in a location between from the first anode electrodes 16, and separated therefrom by portions of the p doped anode layer 12. Accordingly, the position of the p doped emitter layer 51 between the first anode electrodes 16 is not particularly limited. Accordingly, this embodiment has an advantageous effect that a photolithographic step for forming the p emitter layer 51 may be easily performed in steps of manufacturing the pin diode 50.

It is preferable that an area of the p doped emitter layer 51 is set equal to a sum of areas of the p doped emitter layers 13 shown in FIG. 1. For example, a width of the p doped emitter layer 51 in the X direction is set twice as large as a width of the p doped emitter layer 13 in the X direction.

As has been explained heretofore, in the pin diode 50 according to this embodiment, the p doped emitter layer 51 is formed intermediate of and not directly adjacent to the first anode electrodes 16. As a result, a photolithographic step maybe easily performed in steps of manufacturing the pin diode 50.

A plurality of p doped emitter layers 51 may be separately formed as strips in the X direction of the diode 10. In such a case, a sum of the area of the respective p doped emitter layers 51 is equal to the area of the sum of the areas of the p doped emitter layers 13 shown in FIG. 1.

### Third Embodiment

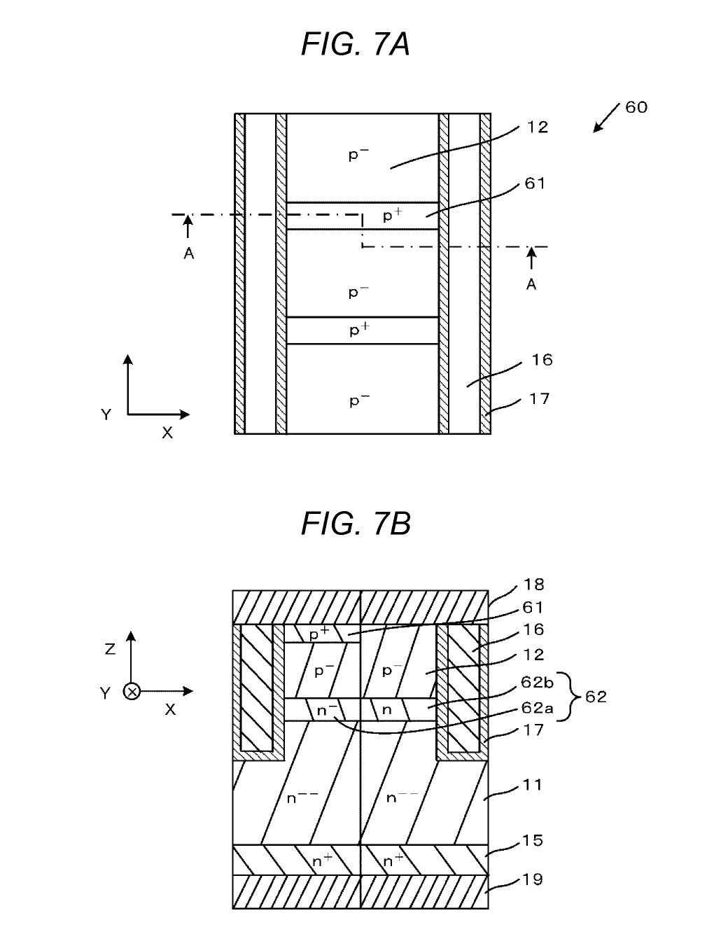

A semiconductor device according to this embodiment is explained by reference to FIG. 7A and FIG. 7B. FIG. 7A and FIG. 7B are views showing the semiconductor device according to this embodiment, wherein FIG. 7A is a plan view of the semiconductor device having the second anode electrode removed for clarity of viewing the underlying structure, and FIG. 7B is a cross-sectional view taken along a line A-A in FIG. 7A and viewed in the direction indicated by arrows with the second anode electrode in place. The line A-A is not a linear line but is a offset line.

In this embodiment, the constitutional elements identical with the corresponding constitutional elements according to the first embodiment are given the same symbols and hence, the explanation of the identical constitutional elements is omitted, and only the elements which differ from the corresponding elements according to the first embodiment are explained. The point which makes this embodiment different from the first embodiment lies in that p doped emitter layers extend in the X direction across the gap between adjacent first anode electrodes 16.

That is, as shown in FIG. 7A and FIG. 7B, in a pin diode 60 according to this embodiment, p doped emitter layers 61 extend in the X direction (second direction) orthogonal to the Y direction. Both ends of each p doped emitter layer 61 are brought into contact with the insulation film 17 covering the first anode electrodes 16.

A plurality of p doped emitter layers 61 are separately arranged, i.e., spaced from one another, in the Y direction. First regions 62a of an n doped barrier layer 62 are arranged below the p doped emitter layers 61. Each second region 62b of the n doped barrier layer 62 is arranged between first regions 62a which also extend between adjacent insulation films 17 covering the first anode electrodes 16.

In this embodiment, it is sufficient that the plurality of p emitter layers 61 are spaced apart in the Y direction, and the spacing between the p emitter layers 61 is not particularly limited.

In the case where the p doped emitter which extends in the Y direction is located between the first anode electrodes 16, when a distance between the first anode electrodes 16 (distance between the centers of the first anode electrodes 16) in the X direction is small, it becomes difficult to perform a photolithographic step during manufacturing of the pin diode.

To the contrary, in this embodiment, the p emitter layers 61 extend in the X direction and thus may be spaced further from adjacent structures of the diode 10, and hence a photolithographic step used in manufacturing of the pin diode 60 is not influenced by the distance between the first anode electrodes 16 in the X direction. Accordingly, this embodiment acquires an advantageous effect that a photolithography step in steps of manufacturing the pin diode 60 may be easily performed even when the distance between the first anode electrodes 16 in the X direction is small.

It is preferable that a sum of the areas of the p doped emitter layers 61 is equal to a sum of areas of the p doped emitter layers 13 shown in FIG. 1A and FIG. 1B.

As has been explained heretofore, the p doped emitter layers 61 extend in the X direction in the pin diode 60 according to this embodiment. As a result, a photolithography step in steps of manufacturing the pin diode 60 maybe easily performed. This arrangement is suitable for the case where a distance between the first anode electrodes 16 in the X direction (distance between centers) is short.

### Fourth Embodiment

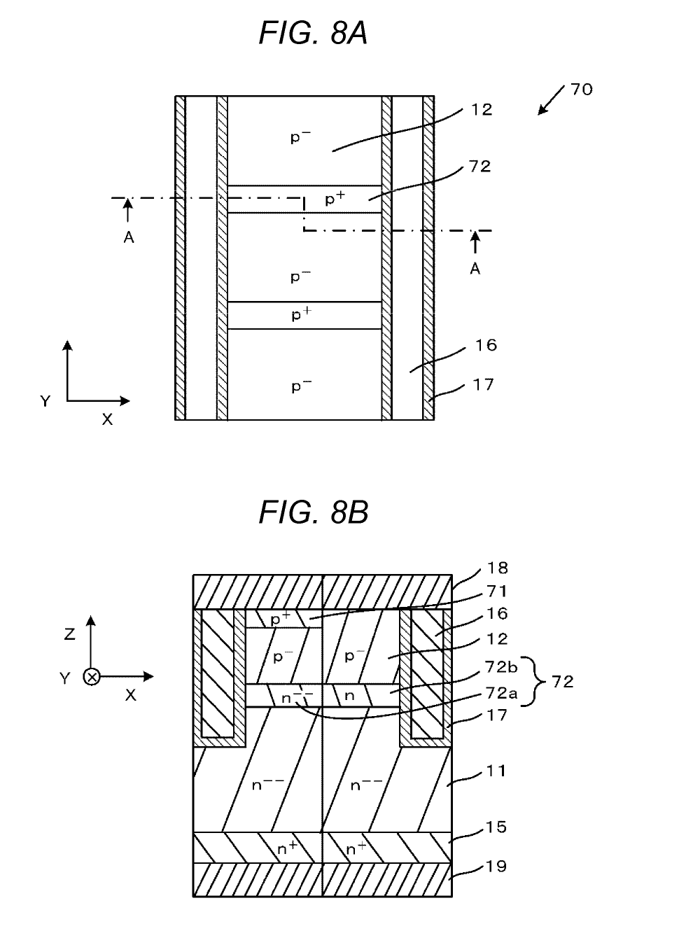

A semiconductor device according to this embodiment is explained by reference to FIG. 8A and FIG. 8B. FIG. 8A and FIG. 8B are views showing the semiconductor device according to this embodiment, wherein FIG. 8A is a plan view of the semiconductor device with the second anode electrode 18 thereof removed for clarity of viewing the underlying structure, and FIG. 8B is a cross-sectional view taken along a line A-A in FIG. 8A and viewed in the direction indicated by arrows with the second anode electrode 18 in place. The line A-A is a offset line.

In this embodiment, the constitutional elements identical with the corresponding constitutional elements according to the first embodiment are given the same symbols and hence, the explanation of the identical constitutional elements is omitted, and only the elements which differ from the corresponding elements according to the first embodiment are explained. The point which makes this embodiment different from the embodiment of FIGS. 7A and 7B lies in that a first dopant concentration in a first region of an n doped barrier layer is set substantially equal to a dopant concentration in an n doped base layer.

That is, as shown in FIG. 8A and FIG. 8B, in a pin diode 70 according to this embodiment, p doped emitter layers 71 are arranged in the same manner as the p doped emitter layers 61 shown in FIG. 7A and FIG. 7B. In an n doped barrier layer 72, a first dopant concentration in first regions 72a positioned below the p doped emitter layers 71 is set substantially equal to a dopant concentration in an n doped base layer 11. Each second region 72b of the n doped barrier layer 72 is located between adjacent first regions 72a extending in the Y direction.

In the n doped barrier layer 72 according to this embodiment, the difference between the n dopant concentration in the first region 72a and the n dopant concentration in the second region 72b is large and hence, this embodiment may enhance an advantageous effect that a path for discharging excess carriers in the n doped base layer 11 is limited to the first regions 72a when the pin diode 70 is turned off.

As has been explained heretofore, in the pin diode 70 according to this embodiment, the n dopant concentration in the first regions 72a of the n doped barrier layer 72 is set substantially equal to the dopant concentration in the n doped base layer 11. Accordingly, the difference in a dopant concentration between the first region 72a and the second region 72b becomes large and hence, this embodiment may acquire an advantageous effect that reverse recovery capability may be further enhanced.

Although the explanation has been made with respect to the case where the p emitter layers 71 are arranged in the same manner as the p emitter layers 61 shown in FIG. 7A and FIG. 7B in this embodiment, the p emitter layers 71 maybe arranged in the same manner as the p emitter layers 13 shown in FIG. 1A and FIG. 1B or the p emitter layer 51 shown in FIG. 6A and FIG. 6B.

### Fifth Embodiment

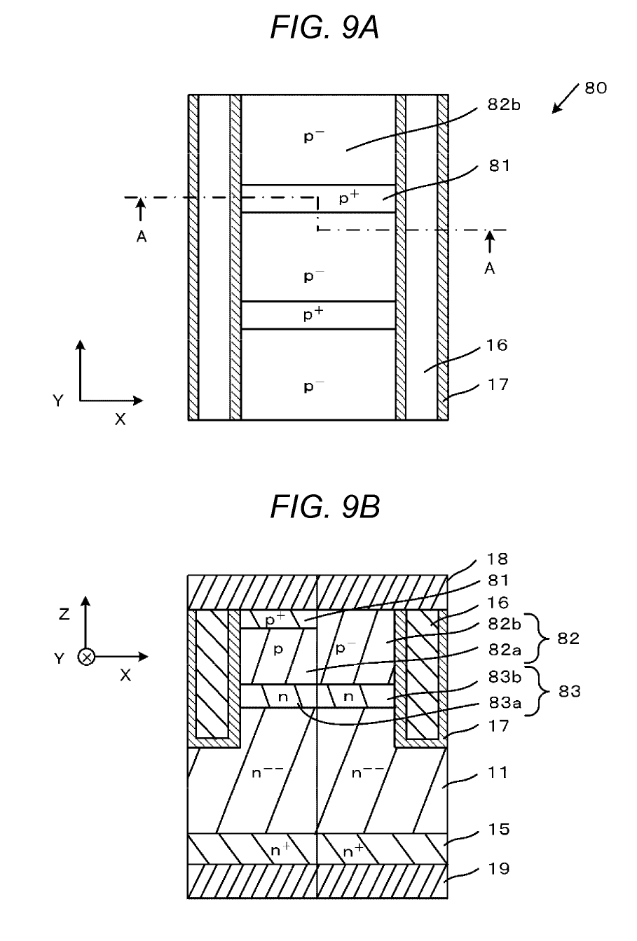

A semiconductor device according to this embodiment is explained by reference to FIG. 9A and FIG. 9B. FIG. 9A and FIG. 9B are views showing the semiconductor device according to this embodiment, wherein FIG. 9A is a plan view of the semiconductor device having the second anode electrode 18 removed for clarity of viewing the underlying structure, and FIG. 9B is a cross-sectional view taken along a line A-A in FIG. 9A and viewed in the direction indicated by arrows with the second anode electrode in place. The line A-A is an offset line.

In this embodiment, the constitutional elements identical with the corresponding constitutional elements according to the first embodiment are given the same symbols and hence, the explanation of the identical constitutional elements is omitted, and only the elements which differ from the corresponding elements according to the first embodiment are explained. The point which makes this embodiment different from the second embodiment lies in that the dopant concentration in a p doped anode layer in a region directly below a p doped emitter layer is higher than the dopant concentration in the p doped anode layer in a region other than the region directly below the p doped emitter layer.

That is, as shown in FIG. 9A and FIG. 9B, in a pin diode 80 according to this embodiment, p doped emitter layers 81 are arranged in the same manner as the p doped emitter layers 61 shown in FIG. 7A and FIG. 7B. In a p doped anode layer 82, consider the regions of the p anode layer 82 directly below the p emitter layers 81 as third regions 82a. Also consider regions of the p anode layer 82 other than the third regions 82a as fourth regions 82b. A p dopant concentration in the third region 82a is higher than a p dopant concentration in the fourth region 82b.

On the other hand, in an n doped barrier layer 83, the n dopant concentration in a first region 83a below the p doped emitter layers 81 is equal to the n dopant concentration in a second region 83b.

Also in this embodiment, when the pin diode 80 is turned off, it is possible to acquire an advantageous effect that a path for discharging excess carriers in an n base layer 11 is limited to the first region 83a.

As has been explained heretofore, according to the pin diode 80 according to this embodiment, in the p doped anode layer 82, the p dopant concentration in the third region 82a directly below the p doped emitter layer 81 is higher than the p dopant concentration in the fourth region 82b of the p doped anode layer 82.

Also in the pin diode 80 according to this embodiment, in the same manner as the pin diode 10 according to the first embodiment, it is possible to obtain the advantageous effect of enhancing reverse recovery capability.

Although an explanation of this embodiment has been made with respect to the case where the p doped emitter layers 81 are arranged in the same manner as the p doped emitter layers 61 shown in FIG. 7A and FIG. 7B, the p doped emitter layers 81 may be arranged in the same manner as the p doped emitter layers 13 shown in FIG. 1A and FIG. 1B or the p emitter layer 51 shown in FIG. 6A and FIG. 6B.

Although the explanation has been made with respect to the case where the n dopant concentration in the first region 83a of the n doped barrier layer 83 is equal to the n dopant concentration in the second region 83b, it is possible to further increase an effect of enhancing reverse recovery capability by setting the n dopant concentration in the first region lower than the n dopant concentration in the second region 83b.

While certain embodiments have been described, these embodiments have been presented by way of examples only, and are not intended to limit the scope of the inventions. Indeed, the novel embodiments described herein may be embodied in a variety of other forms; furthermore, various omissions, substitutions and changes in the form of the embodiments described herein maybe made without departing from the spirit of the inventions. The accompanying claims and their equivalents are intended to cover such forms or modifications as would fall within the scope and spirit of the inventions.

What is claimed is:

1. A semiconductor device comprising:
a first semiconductor layer of a first conductivity type having a first side and a second side opposite to the first side;
a second semiconductor layer of a second conductivity type formed on the first side;
a third semiconductor layer of a second conductivity type partially formed in the second semiconductor layer;
a fourth semiconductor layer of a first conductivity type formed between the first semiconductor layer and the second semiconductor layer, the fourth semiconductor layer facing the third semiconductor layer, the fourth semiconductor layer including a first region which has a first dopant concentration and a second region which has a second dopant concentration higher than the first dopant concentration;
a fifth semiconductor layer of a first conductivity type formed on the second side;
a first conductor and a second conductor, each having an insulation film disposed thereon brought into contact with the first semiconductor layer and the second semiconductor layer, wherein the third semiconductor layer extends inwardly of the second semiconductor layer at a location between the first conductor and the second conductor ; and
a first electrode which is electrically connected with the second semiconductor layer, the third semiconductor layer and the first and second conductors.

2. The semiconductor device according to claim 1, wherein
the first dopant concentration is equal to a dopant concentration of the first semiconductor layer.

3. The semiconductor device according to claim 1, wherein
the second semiconductor layer includes a third region which is positioned between the third semiconductor layer and the fourth semiconductor layer and has a third dopant concentration, and a fourth region which is positioned between the first electrode and the fourth semiconductor layer and has a fourth dopant concentration which is lower than the third dopant concentration.

4. The semiconductor device according to claim 1, wherein the second region of the fourth semiconductor layer, which has a second dopant concentration higher than the first dopant concentration of the first semiconductor region of the fourth semiconductor layer, underlies the third semiconductor layer.

5. The semiconductor device according to claim 4, wherein the third semiconductor layer is disposed in direct contact with the insulation film disposed on the first conductor.

6. The semiconductor device according to claim 4, wherein a first portion of the third semiconductor layer is disposed in direct contact with the insulation film disposed on the first conductor, and a second portion of the third semiconductor layer is disposed in direct contact with the insulation film disposed on the second conductor, and the second semiconductor layer extends between the first and second portions of the third semiconductor layer.

7. The semiconductor device according to claim 4, wherein the third semiconductor layer extends between the insulation film disposed on the first conductor and the insulation film disposed on the second conductor.

8. The semiconductor device according to claim 4, wherein the second semiconductor layer extends between the insulation film disposed on the first conductor and the insulation film disposed on the second conductor, and the third semiconductor layer is disposed within the second semiconductor layer in a location intermediate of the insulation film disposed on the first conductor and the insulation film disposed on the second conductor.

9. The semiconductor device according to claim 4, wherein the second semiconductor layer extends between the insulation film disposed on the first conductor and the insulation film disposed on the second conductor, and the third semiconductor layer includes a first portion disposed within the second semiconductor layer in a location intermediate of the insulation film disposed on the first conductor and the insulation film disposed on the second conductor and a second portion, different than the first portion and spaced therefrom, disposed within the second semiconductor layer in a location intermediate of the insulation film disposed on the first conductor and the insulation film disposed on the second conductor.

10. A pin diode configured for integration with power semiconductor device, comprising:
a doped base layer of a first conductivity type having a first side and a second side;
a cathode located on the first side of the base layer;
a barrier layer of a first conductivity type located on the second side of the base layer, the doped barrier layer having at least a portion thereof having a lower dopant concentration than the remainder thereof;
an anode layer of a second conductivity type located over the doped barrier layer;
an emitter layer of the second conductivity type located on a side of the doped anode layer; and
a first conductor and a second conductor, having an insulative layer thereover, extending along opposed sides of the anode layer and into the base layer; wherein
a portion of the barrier layer having a lower dopant concentration than a remaining portion of the barrier layer is located at a position intermediate of the first and second conductors; and
the emitter layer is located, relative to the first and the second conductor, in the same position as the portion of the barrier layer having a lower dopant concentration than a remaining portion of the barrier layer.

11. The pin diode of claim 10, wherein the barrier layer having a lower dopant concentration than a remaining portion of the barrier layer includes a first portion located in contact with the insulative film of the first conductor.

12. The pin diode of claim 10, wherein the barrier layer having a lower dopant concentration than a remaining portion of the barrier layer includes a second portion located in contact with the insulative film of the second conductor, and the anode layer is interposed between the first portion and second portion of the barrier layer.

13. The pin diode of claim 10, wherein the emitter layer includes a first portion thereof extending between the insulative film of the first conductor and the insulative film of the second conductor.

14. The pin diode of claim 13, further comprising a first electrode in contact with the first and second conductors, the emitter layer and the anode layer, and the emitter layer extends inwardly of a surface of the anode layer contacting the first electrode.

15. The pin diode of claim 14, wherein the anode layer includes a first portion, having a dopant concentration of the second conductivity type dopant, and a second portion, having a dopant concentration of the second conductivity type dopant greater than that in the first portion of the doped anode layer, in a location extending directly between the emitter layer and the base layer.

16. The pin diode of claim 15, wherein the anode layer further includes a third portion, having a dopant concentration lower than the first and second portions, in direct contact with the first electrode.

17. A method of providing a pin diode having improved reverse recovery capability, comprising:
providing a doped anode layer;
providing a doped barrier layer intermediate of a doped anode layer and a doped base layer;
providing at least one emitter layer on a side of the doped anode layer;
contacting the at least one emitter layer on a side of the doped anode layer with an electrode;
providing, in the doped barrier layer, a region of higher dopant concentration than remaining regions of the doped barrier layer;
aligning, in a current flow direction of the pin diode, the location of the region of the barrier layer having higher dopant concentrations with the location of the doped emitter; and
flowing a current through the barrier layer to the electrode, wherein the current preferentially flows through the region of the barrier layer having the higher dopant concentration and the doped emitter to the first electrode.

18. The method of claim 17, further comprising providing a first conductor and a second conductor disposed on opposite sides of the doped anode layer, the doped barrier layer and the at least one emitter layer.

19. The method of claim 18, further comprising:
contacting the doped anode layer with the electrode at a location intermediate of the doped emitter and one of the first and second conductors.

20. The method of claim 18, further comprising:
contacting the doped anode layer with the electrode at a location intermediate of the doped emitter and both the first and second conductors.
